(19) United States
(12) Patent Application Publication
(10) Pub. No.: US 2025/0040309 A1
(43) Pub. Date: Jan. 30, 2025

(54) DISPLAY APPARATUS

(71) Applicant: LG Display Co., Ltd., Seoul (KR)

(72) Inventors: Hye Sun JUNG, Paju-si (KR); Bung Goo KIM, Paju-si (KR); Hyoung Ho AHN, Paju-si (KR); Hee Won LEE, Paju-si (KR); Jun Young JO, Paju-si (KR); Sang Hak SHIN, Paju-si (KR); Jae Kwang LEE, Paju-si (KR); Hyoung Sun PARK, Paju-si (KR); Pyung Ho CHOI, Paju-si (KR); Tae Yoon KIM, Paju-si (KR)

(21) Appl. No.: 18/781,581

(22) Filed: Jul. 23, 2024

(30) Foreign Application Priority Data
Jul. 27, 2023 (KR) 10-2023-0098313

(51) Int. Cl. H01L 33/44; H01L 25/075; H01L 33/62

(52) U.S. Cl. CPC H01L 33/44; H01L 25/0753; H01L 33/62

(57) ABSTRACT

A display apparatus according to an exemplary embodiment is disclosed. A display apparatus according to an exemplary embodiment includes a substrate having a bending region between an active area and a pad area. The display apparatus includes a planarization film on the active area and the pad area in the substrate. The display apparatus includes a first organic film coated on the planarization film, a second organic film coated on the first organic film, and a third organic film coated on the second organic film. The third organic film is formed such that an upper surface thereof is flattened in the active region. The display apparatus includes a plurality of light-emitting elements disposed on the third organic film.

### CROSS-REFERENCE TO RELATED APPLICATION

This application claims priority to and the benefit of Korean Patent Application No. 10-2023-0098313, filed Jul. 27, 2023, the disclosure of which is incorporated herein by reference in its entirety.

### BACKGROUND

### Technical Field

The present disclosure relates to a display apparatus.

### Description of the Related Art

As flat display apparatuses, liquid crystal display apparatuses and organic light-emitting display apparatuses are used. The organic light-emitting display apparatus has the advantage of improved light-emitting efficiency, fast response speed, a wide viewing angle, and the like compared to the liquid crystal display apparatus. However, since the organic light-emitting display apparatus still has low light emission efficiency and includes organic materials, the organic light-emitting display apparatus is vulnerable to moisture and thus reliability and lifespan may be reduced.

Recently, a micro light-emitting diode display apparatus being an inorganic light-emitting display apparatus has been proposed. The micro light-emitting diode display apparatus produces an image by disposing an inorganic light-emitting diode with a size of 100 μm or less in each pixel.

### BRIEF SUMMARY

The micro light-emitting diode display apparatus may be manufactured so that at least a portion thereof may be bent. However, in the process of manufacturing the micro light-emitting diode display apparatus, the thickness of a bending portion or its adjacent portion is not formed flat (or to be planar), which causes a problem that a micro light-emitting diode is improperly transferred when it is transferred to the bending portion or its adjacent portion. The inventors of the present disclosure have appreciated various technical problems in the related art, including the above-identified technical problem and the various embodiments provided herein is directed to addressing the problems in the related art.

The present disclosure provides a display apparatus capable of improving the transfer yield of micro light-emitting diodes.

It should be noted that technical benefits of the present disclosure are not limited to the above-described benefits, and other benefits of the present disclosure will be apparent to those skilled in the art from the following descriptions.

A display apparatus according to embodiments of the present specification may include a substrate having a bending region between an active area and a pad area. The display apparatus may include a planarization film on the active area and the pad area in the substrate. The display apparatus may include a first organic film coated on the planarization film. The display apparatus may include a second organic film coated on the first organic film. The display apparatus may include a third organic film coated on the second organic film. The third organic film is formed such that an upper surface thereof is flattened in the active region (or the upper surface being planar in the active region). The display apparatus may include a plurality of light-emitting elements disposed on the third organic film.

A display apparatus according to embodiments of the present specification may include a substrate having a bending region between an active area and a pad area; a planarization film formed on the active area and the pad area in the substrate; an organic film coated on the planarization film and on the substrate exposed in the bending region, wherein the organic film is formed so that an upper surface thereof is flattened in the active area; and a plurality of light-emitting elements transferred to the flattened organic film.

According to the present disclosure, a photoresist pattern is disposed on a lower organic film corresponding to a bending region, and then an upper organic film is coated on the lower organic film on which the photoresist pattern is disposed, thereby flattening the upper organic film to prevent non-transfer of light-emitting elements.

According to the present disclosure, it is possible to prevent non-transfer of light-emitting elements by using the photoresist pattern, which may lead to process optimization.

The effects of the present specification are not limited to the above-mentioned effects, and other effects that are not mentioned will be apparently understood by those skilled in the art from the following description and the appended claims.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a diagram illustrating a display apparatus according to one embodiment of the present disclosure;

FIG. 2 is an enlarged view of a region ‘A’ in FIG. 1;

FIG. 3 is a diagram illustrating a partial area of a pixel;

FIG. 4 is a cross-sectional view taken along line I-I′ in FIG. 3;

FIG. 5 is a cross-sectional view taken along line II-II′ in FIG. 3;

FIG. 6 is a cross-sectional view taken along line III-III′ in FIG. 3;

FIG. 7 is a cross-sectional view illustrating an example in which a main light-emitting element and a sub light-emitting element are electrically connected to a pixel driving circuit;

FIG. 8 is a diagram illustrating a display apparatus according to another embodiment of the present disclosure;

FIG. 9 is a cross-sectional view taken along line IV-IV′ in FIG. 8;

FIGS. 10A to 10B are diagrams for describing a shape of the display apparatus shown in FIG. 1;

FIG. 11 is a diagram illustrating a longitudinal sectional structure of the display apparatus shown in FIG. 1;

FIGS. 12A to 12C are drawings for illustrating a principle of coating an organic film in a bending region by comparison;

FIG. 13 is a diagram illustrating a method of manufacturing a display apparatus according to an embodiment of the present disclosure; and

FIGS. 14A to 14I are diagrams illustrating the respective processes of manufacturing method shown in FIG. 13.

### DETAILED DESCRIPTION

Advantages and features of the present specification and methods of achieving them will become apparent with reference to preferable embodiments, which are described in detail, in conjunction with the accompanying drawings. However, the present specification is not limited to the embodiments to be described below and may be implemented in different forms, the embodiments are only provided to completely disclose the present disclosure and completely convey the scope of the present disclosure to those skilled in the art, and the present specification is defined by the disclosed claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals indicate the same components throughout the specification. Further, in describing the present disclosure, when it is determined that a detailed description of related known technology may unnecessarily obscure the gist of the present disclosure, the detailed description thereof will be omitted.

When ‘including,’ ‘having,’ ‘consisting,’ and the like mentioned in the present specification are used, other parts may be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

Although first, second, and the like are used to describe various components, these components are not limited by these terms. These terms are only used to distinguish one component from another. Accordingly, a first component, which is mentioned, below may also be a second component within the technical spirit of the present disclosure.

The same reference numerals may refer to substantially the same elements throughout the present disclosure.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

In an embodiment, a photoresist pattern is disposed on the lower organic film corresponding to a bending region, and then the upper organic film is coated on the lower organic film on which the photoresist pattern is disposed, in order to flatten the upper organic film to prevent non-transfer of light-emitting elements.

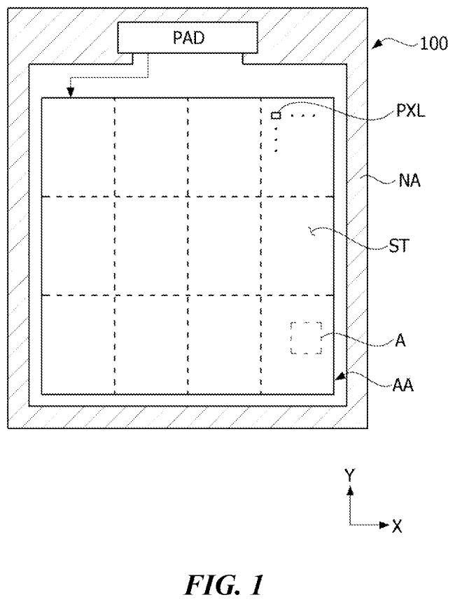

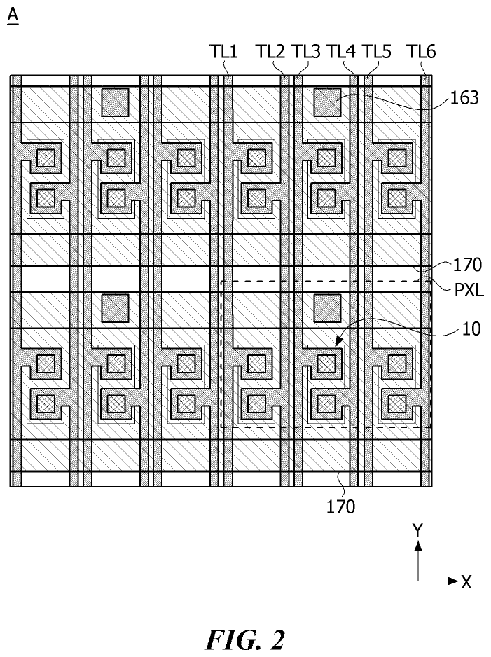

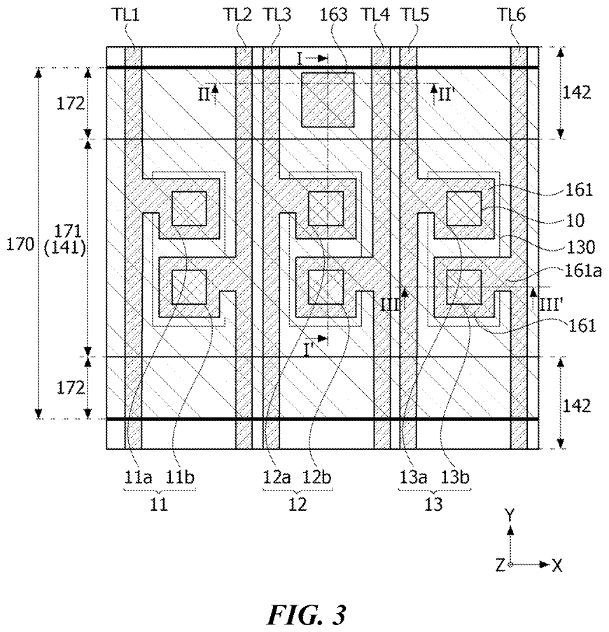

FIG. 1 is a diagram illustrating a display apparatus according to one embodiment of the present specification; FIG. 2 is an enlarged view of an area A of FIG. 1; FIG. 3 is a diagram illustrating a partial area of a pixel.

Referring to FIGS. 1 and 2, a display apparatus according to one embodiment of the present specification includes a display panel 100 that visually reproduces an input image. The display panel 100 may include a display area AA in which an image is displayed and a non-display area NA in which the image is not displayed. In the non-display area NA, various wire and driving circuits may be mounted and a pad part PAD to which integrated circuits, printed circuits, etc., are connected may be disposed.

A plurality of light emitting elements 10 disposed in the display area AA to form pixels PXL may be micro-sized inorganic light emitting elements. The inorganic light emitting elements may be grown on a silicon wafer and then attached to the display panel through a transfer process.

The transfer process of the light emitting element 10 may be performed for each pre-divided area. In FIG. 1, the display area AA is divided into twelve transfer areas STs, but the size or number of divisions of the transfer areas is not limited thereto. The transfer process may be performed sequentially or simultaneously on first to twelfth transfer areas STs. In the transfer area ST, blue, green, and red light emitting elements 10 may be sequentially transferred, respectively.

In the non-display area NA, a data driving circuit or a gate driving circuit may be disposed, and wires for supplying control signals to control these driving circuits may be disposed. Here, the control signals may include various timing signals including a clock signal, an input data enable signal, and a synchronization signal, and may be received through the pad portion PAD.

The pixels PXL may be driven by a pixel driving circuit. The pixel driving circuit may receive a driving voltage, an image signal (digital signal), a synchronization signal synchronized with the image signal, etc., and output an anode voltage and a cathode voltage of the light emitting element 10 to drive a plurality of pixels. The driving voltage may be a high potential voltage (EVDD). The cathode voltage may be a low potential voltage (EVSS) commonly applied to the pixels. The anode voltage may be a voltage corresponding to the pixel data value of the image signal. The pixel driving circuit may be disposed in the non-display area NA or a lower portion of the display area AA.

Each of the pixels PXL may include a plurality of sub-pixels each having a different color. For example, the plurality of pixels may include a red sub-pixel in which the light emitting element 10 that emits light in a red wavelength is disposed, a green sub-pixel in which the light emitting element 10 that emits light in a green wavelength is disposed, and a blue sub-pixel in which the light emitting element 10 that emits light in a green wavelength is disposed. The plurality of pixels may further include white pixels.

Referring to FIGS. 2 and 3, the plurality of pixels PXL may be sequentially arranged in a first direction (X-axis direction) and a second direction (Y-axis direction). Within the pixels of the display area AA, a plurality of sub-pixels of the same color may be arranged. For example, each of the plurality of pixels may include a first red sub-pixel in which a first-first light emitting element 11a that emits light in a red wavelength is disposed, a second red sub-pixel in which a first-second light emitting element 11b emits light in a red wavelength disposed, a first green sub-pixel in which a second-first light emitting element 12a emitting light in a green wavelength is disposed, a second green sub-pixel in which a second-second light emitting element 12b emitting light in a green wavelength is disposed, a first blue sub-pixel in which a third-first light emitting element 13a emitting light in a blue wavelength disposed, and a second blue sub-pixel in which a third-second light emitting element 13b emitting light in a blue wavelength is disposed. The first-first light emitting element 11a, the second-first light emitting element 12a, and the third-first light emitting element 13a may be interpreted as main light emitting elements. The first-second light emitting element 11b, the second-second light emitting element 12b, and the third-second light emitting element 13b may be interpreted as sub-light emitting elements.

One sub-pixel includes one or more light emitting elements, and if one light emitting element becomes defective, the luminance of another light emitting element may be increased to adjust the luminance of the sub-pixel. However, it is not necessarily limited to thereto, and one sub-pixel may include only one light emitting element.

Each of a plurality of first electrodes 161 may be disposed in a lower portion of the light emitting element 10 and may be selectively connected to a plurality of signal wirings TL1 to TL6 by extension portions 161a. A high potential voltage may be applied to the pixel driving circuit through the signal wirings TL to TL6. The signal wirings TL to TL6 and the first electrode 161 may be formed as an electrode pattern integrated in an electrode patterning process.

Illustratively, the first signal wiring TL1 may be connected to an anode electrode of the first red sub-pixel, and the second signal wiring TL2 may be connected to an anode electrode of the second red sub-pixel. The third signal wiring TL3 may be connected to an anode electrode of the first green sub-pixel, and the fourth signal wiring TL4 may be connected to an anode electrode of the second green sub-pixel. The fifth signal wiring TL5 may be connected to an anode electrode of the first blue sub-pixel, and the sixth signal wiring TL6 may be connected to an anode electrode of the second blue sub-pixel. If one sub-pixel includes only one light emitting element, the number of signal wirings TL may be reduced by half.

A second electrodes 170 may be a cathode electrode that is arranged in each row to apply a cathode voltage to the light emitting element 10 continuously arranged in the first direction (X-axis direction). The plurality of second electrodes 170 may be arranged to be spaced apart from each other in the second direction (Y-axis direction). The plurality of second electrodes 170 may be connected to the cathode voltage through a contact electrode 163. Each of the plurality of second electrodes 170 may be electrically connected to the contact electrode 163. However, it is not necessarily limited thereto, and the second electrode 170 may include one electrode layer instead of being divided into a plurality of electrodes to function as a common electrode.

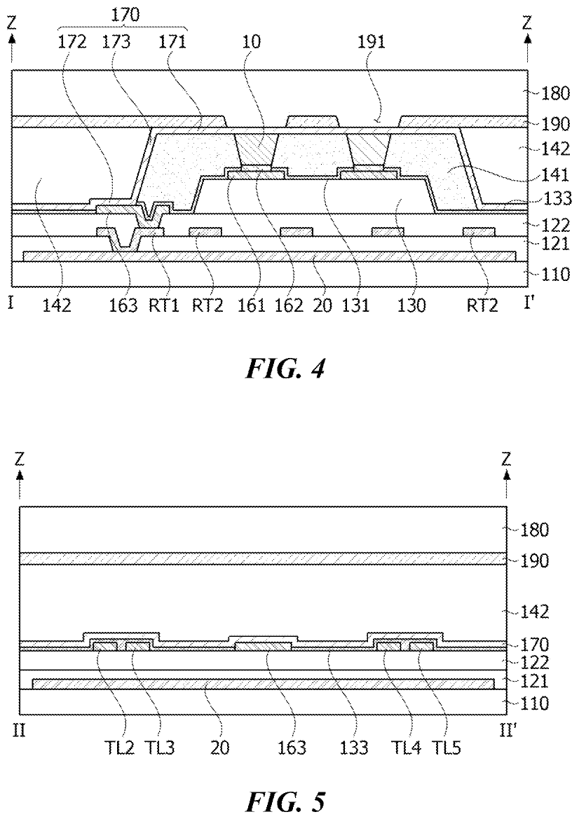

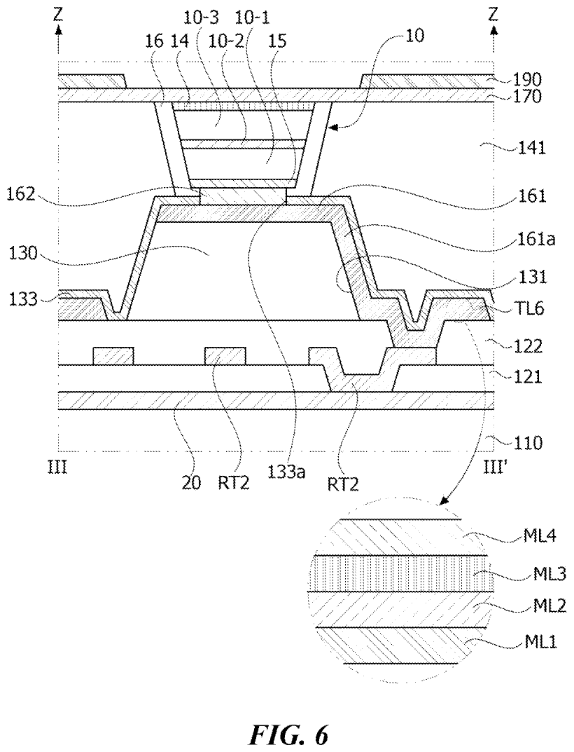

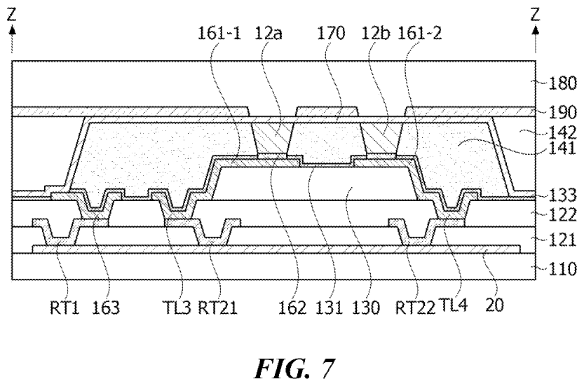

FIG. 4 is a cross-sectional view taken along line I-I′ in FIG. 3. FIG. 5 is a cross-sectional view taken along line II-II′ in FIG. 3. FIG. 6 is a cross-sectional view taken along line III-III′in FIG. 3. FIG. 7 is a cross-sectional view showing an example in which two light emitting elements are connected to a pixel driving circuit.

Referring to FIGS. 3 to 5, a display apparatus according to an embodiment includes a plurality of first electrodes 161 and a contact electrode 163 disposed on a substrate 110, a plurality of light emitting elements 10 disposed on a plurality of first electrodes 161, a first optical layer 141 disposed between the plurality of light emitting elements 10, and a second electrode 170 disposed on the plurality of light emitting elements 10.

The substrate 110 may be made of plastic with flexibility. For example, the substrate 110 may be made of a single-layer or multi-layer substrate of a material selected from polyimide, polyethylene terephthalate, polyethylene naphthalate, polycarbonate, polyethersulfone, and polyarylate, polysulfone, and cyclic-olefin copolymer, but is not limited thereto. For example, the substrate 110 may be a ceramic substrate or a glass substrate.

A pixel driving circuit 20 may be disposed in the display area AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes a plurality of thin film transistors, it may be formed on the substrate 110 by a thin film transistor (TFT) manufacturing process. In embodiments, the pixel driving circuit 20 may be a collective term for a plurality of thin film transistors electrically connected to the light emitting element 10.

The pixel driving circuit 20 may be a driving driver manufactured using a metal-oxide-silicon field effect transistor (MOSFET) manufacturing process on a single crystal semiconductor substrate 110. The driving driver may include a plurality of pixel driving circuits to drive a plurality of sub-pixels. When the pixel driving circuit 20 is implemented as a driving driver, after an adhesive layer is disposed on the substrate 110, the driving driver may be mounted on the adhesive layer by a transfer process.

A buffer layer 121 covering the pixel driving circuit 20 may be disposed on the substrate 110. The buffer layer 121 may be made of an organic insulating material, for example, photosensitive photo acryl or photosensitive polyimide, but is not limited thereto.

The buffer layer 121 may be used by stacking an inorganic insulating material, for example, silicon nitride (SiNx) or silicon oxide (SiO₂) in a multiple layers, and may be used by stacking an organic insulating material and an inorganic insulating material in multiple layers.

An insulating layer 122 may be disposed on the buffer layer 121. The insulating layer 122 may be made of an organic insulating material, for example, photosensitive photo acryl or photosensitive polyimide, but is not limited thereto. Connection wirings RT1 and RT2 may be disposed on the buffer layer 121. The connection wirings RT1 and RT2 may be connected by the corresponding signal wirings TL1 to TL6 or may be connected to the signal wirings TL1 to TL6. The connection wirings RT1 and RT2 may include a plurality of wiring patterns disposed on different layers with one or more insulating layers interposed therebetween. The wiring patterns disposed on the different layers may be electrically connected via contact holes through which the insulating layers are passed.

A plurality of bank patterns 130 may be disposed on the insulating layer 122. At least one light emitting element 10 may be disposed on each bank pattern 130. For example, a first light emitting element 11 may be disposed on a first bank pattern 130, a second light emitting element 12 is disposed on a second bank pattern 130, and a third light emitting element 13 may be disposed on a third bank pattern 130.

The bank patterns 130 may be made of an organic insulating material, for example, photosensitive acryl or photosensitive polyimide, but is not limited thereto. The bank pattern 130 may guide a position to which the light emitting element 10 is to be attached in the transfer process of the light emitting element 10. The bank pattern 130 may be omitted.

A solder pattern 162 may be disposed on the first electrode 161. The solder pattern 162 may be made of indium (In), tin (Sn), or an alloy thereof, but is not limited thereto.

The plurality of light emitting elements 10 may each be mounted on the solder pattern 162. One pixel may include light emitting elements 10 of three colors. The first light emitting element 11 may be a red light emitting element, the second light emitting element 12 may be a green light emitting element, and the third light emitting element 13 may be a blue light emitting element. Two light emitting elements may be mounted in each sub-pixel.

A first optical layer 141 may cover the plurality of light emitting elements 10 and the bank pattern 130. Accordingly, the first optical layer 141 may cover between the plurality of light emitting elements 10 and between the plurality of bank patterns 130. The first optical layer 141 may extend in the first direction (X) and be spaced apart in the second direction (Y) to be separated between rows of pixels.

The first optical layer 141 may include an organic insulating material in which fine metal particles such as titanium dioxide particles are dispersed. Light emitted from the plurality of light emitting elements 10 may be scattered by fine metal particles dispersed in the first optical layer 141 to be emitted externally.

The second electrode 170 may be disposed on the plurality of light emitting elements 10. The second electrode 170 may be commonly connected to the plurality of pixels PXL. The second electrode 170 may be a thin electrode through which light is transmitted. The second electrode 170 may be a transparent electrode material, for example, indium tin oxide (ITO), but is not necessarily limited thereto.

The second electrode 170 may extend in the first direction (X-axis direction) and be spaced apart in the second direction (Y-axis direction). The second electrode 170 may include a first area 171 disposed on a top surface of the light emitting element 10 and a top surface of the first optical layer 141, a second area 172 in contact with the contact electrode 163 and electrically connected to the contact electrode 163, and a third area 173 disposed on a side of the first optical layer 141 and connecting the first area 171 and the second area 172.

On a plane, each of the plurality of second electrodes 170 may overlap the first optical layer 141, and the second area 172 may cover a plane outside the first optical layer 141.

The second optical layer 142 may be an organic insulating material surrounding the first optical layer 141. The second optical layer 142 may be disposed on the insulating layer 122 together with the first optical layer 141. The first optical layer 141 and the second optical layer 142 may include the same material (e. g., siloxane). For example, the first optical layer 141 may be siloxane containing titanium oxide (TiOx), and the second optical layer 142 may be siloxane not containing titanium oxide (TiOx). However, it is not necessarily limited to thereto, and the first optical layer 141 and the second optical layer 142 may be formed of the same material or may be formed of different materials.

According to an embodiment, since the second area 172 of the second electrode 170 is connected to the contact electrode 163 in an overall flat state, excessive stress is not concentrated at the point of connection with the contact electrode 163. Therefore, it is possible to effectively prevent cracks from occurring in the second electrode 170.

The second optical layer 142 may cover the second area 172 and the third area 173 of the second electrode 170. The top surface of the second optical layer 142 and the top surface of the first area 171 of the second electrode 170 may be coplanar. In other words, the first optical layer 141 and the second optical layer 142 may function as planarization layers. As a result, a pattern of a black matrix 190 may be easily formed on the first optical layer 141 and the second optical layer 142 because there is no step on the surface where the black matrix 190 is formed. However, it is not necessarily limited to thereto, and the top surfaces of the second optical layer 142 and the second electrode 170 may have different heights.

The black matrix 190 may be an organic insulating material to which black pigment is added. Beneath the black matrix 190, the second electrode 170 may be in contact with the contact electrode 163. A transmission hole 191 may be formed between the patterns of the black matrix 190, through which light emitted from the light emitting element 10 is externally emitted. By the black matrix 190, the problem of mixing of light emitted from neighboring light emitting elements 10 by the first optical layer 141 may be improved.

The cover layer 180 may be an organic insulating material for covering the black matrix 190 and the second electrode 170. In FIG. 3, the configuration of the black matrix 190 and the cover layer 180 is omitted.

The contact electrode 163 is electrically connected to the first connection wiring RT1 disposed on a lower portion thereof, and the first connection wiring RT1 may be connected to the pixel driving circuit 20. Accordingly, the second electrode 170 may be applied with a cathode voltage through the contact electrode 163. The first electrode 161 may be electrically connected to the second connection wiring RT2. This will be described later.

Referring to FIG. 5, the contact electrode 163 and signal wirings TL1 to TL6 may be disposed on the same plane. The pixel driving circuit 20 may be disposed on a lower portion of the contact electrode 163 and the signal wirings TL1 to TL6. When the pixel driving circuit 20 is a driving driver, a plurality of driving drivers may be disposed in the display panel.

A passivation layer 133 may expose the contact electrode 163 so that the contact electrode 163 and the second electrode 170 are electrically connected. In addition, the passivation layer 133 may insulate the signal wirings TL2 to TL5 and the second electrode 170.

Referring to FIG. 6, a connection portion 161a of the first electrode 161 extends to one side surface 131 of the bank pattern 130 and is electrically connected to the connection wiring RT2 disposed on the insulating layer 122.

The first electrode 161, the connection portion 161a, the signal wiring TL, and/or the connection wirings RT1 and RT2 may include a single or multi-layer metal layer selected from titanium (Ti), molybdenum (Mo), and aluminum (Al). The first electrode 161, the connection portion 161a, the signal wiring TL and/or the connection wirings RT1 and RT2 may be formed in a multi-layer structure including a first layer ML1, a second layer ML2, a third layer ML3, and a four layer ML.

The first layer ML1 and the third layer ML3 may include titanium (Ti) or molybdenum (Mo). The second layer ML2 may include aluminum (Al). The fourth layer ML4 may include a transparent conductive oxide layer such as indium tin oxide (ITO) or indium zinc oxide (IZO), which has good adhesion to the solder pattern 162, corrosion resistance, and acid resistance.

The first layer ML1, the second layer ML2, the third layer ML3, and the fourth layer ML4 may be sequentially deposited and then patterned by performing a photolithography process and an etching process.

The passivation layer 133 may be disposed on the first electrode 161 and the signal wiring TL and may include an opening hole 133a exposing the solder pattern 162.

The light emitting element 10 may include a first conductive type semiconductor layer 10-1, an active layer 10-2 disposed on the first conductive type semiconductor layer 10-1, and a second conductive type semiconductor layer 10-3 disposed on the active layer 10-2. A first driving electrode 15 may be disposed on a lower portion of the first conductive type semiconductor layer 10-1, and a second driving electrode 14 may be disposed on an upper portion of the second conductive type semiconductor layer 10-3.

The light emitting element 10 may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, and the like.

The first conductivity type semiconductor layer 10-1 may be implemented as a compound semiconductor such as Group III-V, Group II-VI, etc., and may be doped with a first dopant. The first conductive type semiconductor layer 10-1 may be formed of any one or more of the semiconductor materials having a composition formula of Alₓ₁In_{y1}Ga_{(1-x1-y1)}N (0≤x1≤1, 0≤y1≤1, 0≤x1+y1≤1), InAlGaN, AlGaAs, GaP, GaAs, and AlGaInP, but is not limited thereto. When the first dopant is an n-type dopant such as Si, Ge, Sn, Se, Te, etc., the first conductive type semiconductor layer 10-1 may be an n-type nitride semiconductor layer. However, when the first dopant is a p-type dopant, the first conductive type semiconductor layer 10-1 may be a p-type nitride semiconductor layer.

The active layer 10-2 is a layer in which electrons (or holes) injected through the first conductive type semiconductor layer 10-1 meet holes (or electrons) injected through the second conductive type semiconductor layer 10-3. The active layer 10-2 may generate light that transitions to lower energy levels as the electrons and holes are recombined, and has a corresponding wavelength.

The active layer 10-2 may have any one of a single well structure, a multi-well structure, a single quantum well structure, a multi quantum well (MQW) structure, a quantum dot structure, or a quantum line structure, and the structure of the active layer 10-2 is not limited thereto. The active layer 10-2 may generate light in a visible light wavelength band. Illustratively, the active layer 10-2 may output light in any one of blue, green, and red wavelength bands.

The second conductive type semiconductor layer 10-3 may be disposed on the active layer 10-2. The second conductive type semiconductor layer 10-3 may be implemented as a compound semiconductor such as Group III-V, Group II-VI, etc., and the second conductive type semiconductor layer 10-3 may be doped with a second dopant. The second conductive type semiconductor layer 10-3 may be formed from semiconductor materials having a composition formula of Inₓ₂Al_{y2}Ga_{1-x-2+y2}N (0≤x2≤1, 0≤y2≤1, 0≤x2+y2≤1) or materials selected from AllInN, AlGaAs, GaP, GaAs, GaAsP, and AlGaInP. When the second dopant is a p-type dopant such as Mg, Zn, Ca, Sr, Ba, etc., the second conductive type semiconductor layer 10-3 doped with the second dopant may be a p-type semiconductor layer. When the second dopant is an n-type dopant, the second conductive type semiconductor layer 10-3 may be an n-type nitride semiconductor layer.

A reflective layer 16 may be disposed on a side surface and lower portion of the light emitting element 10. The reflective layer 16 may have a structure in which a reflective material is dispersed in a resin layer, but is not necessarily limited to thereto. Illustratively, the reflective layer 16 may be manufactured as a reflector of various structures. Light emitted from the active layer 10-2 by the reflective layer 16 may be reflected upward to increase light extraction efficiency.

Although the embodiment is described as a vertical structure in which the driving electrodes 14 and 15 are disposed on the upper and lower portion of the light-emitting structure, the light-emitting device may have a lateral structure or a flip chip structure in addition to the vertical structure.

Referring to FIG. 7, a main light emitting element 12a and sub-light emitting element 12b of the sub-pixel may be disposed on the bank pattern 130. The second light emitting element 12 will be illustratively described. A first-first electrode 161-1 connected to the main light emitting element 12a may extend to one side surface of the bank pattern 130 to be electrically connected to the second-first connection wiring RT21 disposed on a lower portion thereof. The first-second electrode 161-2 connected to the sub-light emitting element 12b may extend to the other side surface of the bank pattern 130 to be electrically connected to the second-second connection wiring RT22 disposed on a lower portion thereof.

The pixel driving circuit 20 may apply an anode voltage to the main light emitting element 12a by the second-first connection wiring RT21, and may apply an anode voltage to the sub-light emitting element 12b by the second-second connection wiring RT22. The pixel driving circuit 20 may apply a cathode voltage to the main light emitting element 12a and the sub-light emitting element 12b through the first connection wiring RT1 and the second electrode 170.

The pixel driving circuit 20 may adjust luminance by driving only the main light emitting element 12a, or may adjust luminance by simultaneously driving the main light emitting element 12a and the sub-light emitting element 12b. If the main light emitting element 12a is darkened, the luminance may be adjusted by driving only the sub-light emitting element 12b.

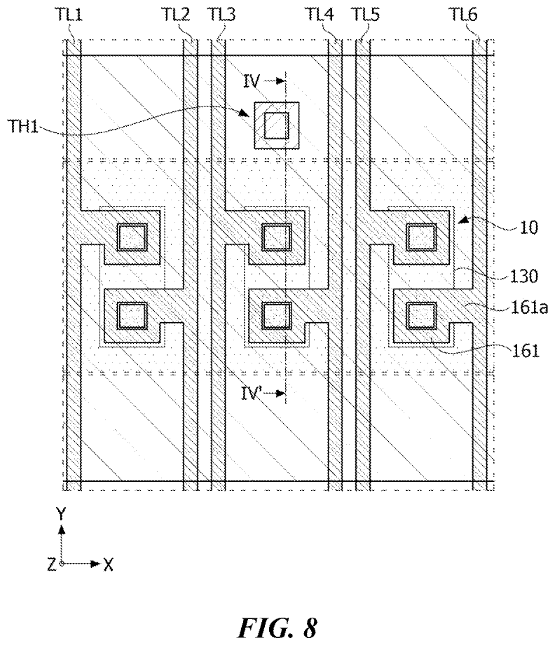

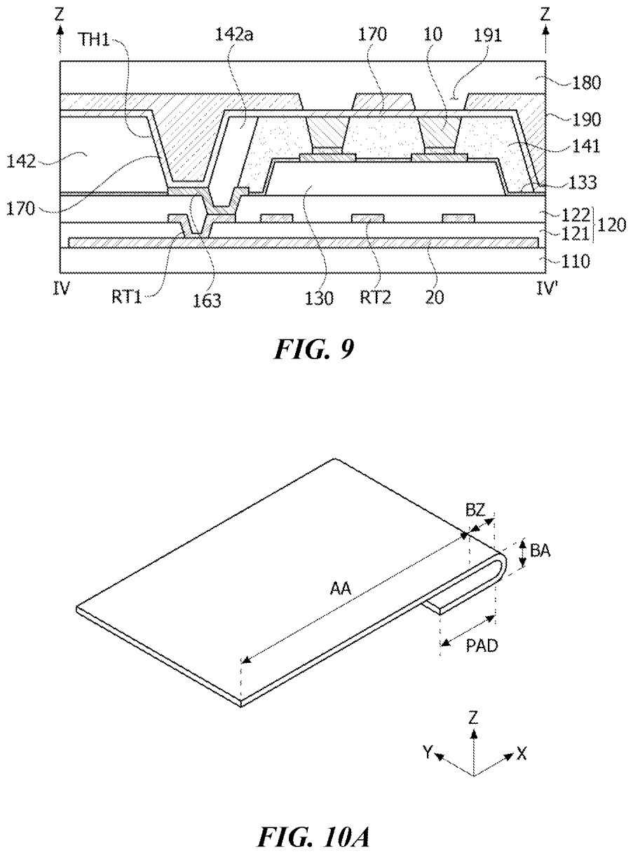

FIG. 8 is a diagram illustrating a display apparatus according to another embodiment of the present specification. FIG. 9 is a cross-sectional view taken along line IV-IV′ in FIG. 8.

Referring to FIGS. 8 and 9, the second electrode 170 may be electrically connected to the contact electrode 163 via a contact hole TH1 formed in the second optical layer 142. The second optical layer 142 may include the contact hole TH1 exposing the contact electrode 163. The second electrode 170 may be inserted into the contact hole TH1 of the second optical layer 142 and may be in contact with an upper surface of the contact electrode 163. The contact hole TH1 may be formed in an outer area of the pixel.

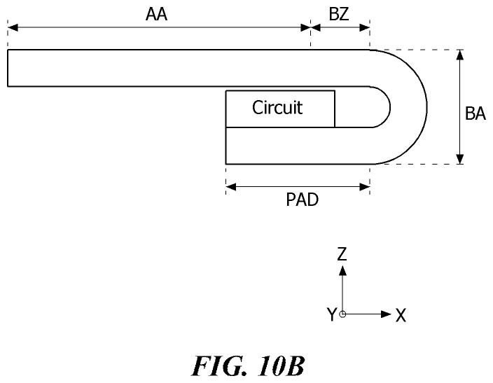

FIGS. 10A to 10B are diagrams for describing a shape of the display apparatus shown in FIG. 1.

Referring to FIGS. 10A to 10B, a display apparatus according to an embodiment of the present disclosure may include a display area or an active area AA, a bezel area BZ corresponding to a non-display area, a bending region BA, and a pad portion PAD.

The bending region BA may be formed between the bezel area BZ and the pad portion PAD and may be bent. As the bending region BA is bent, the pad portion PAD may be placed beneath the display panel 100.

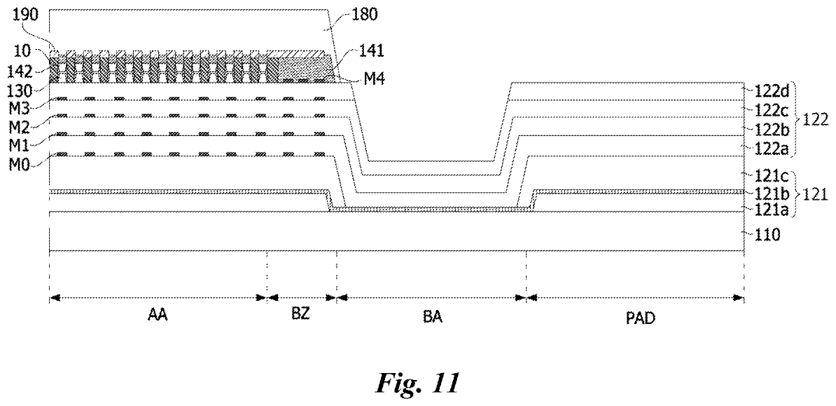

FIG. 11 is a diagram illustrating a longitudinal sectional structure of the display apparatus shown in FIG. 1.

Referring to FIG. 11, the display apparatus according to an embodiment of the present disclosure may include a substrate 110, a buffer layer 121, an insulating layer 122, bank patterns 130, a first optical layer 141, a second optical layer 142, a black matrix 190, and a cover layer 180. Here, the buffer layer 121 may include a multi-buffer layer 121a, an adhesive layer 121b, and a planarization film 121c, and an insulating layer 122 may include a via contact layer 122a, a first organic film 122b, a second organic film 122c, a third organic film 122d, and wire patterns M0, M1, M2, M3, and M4.

The multi-buffer layer 121a may be disposed on the substrate 110. The multi-buffer layer 121a may be disposed only in the active area AA, the bezel area BZ, and the pad area PAD, except for the bending region BA. The multi-buffer layer 121a may be formed of an organic insulating material, such as, but not limited to, a photosensitive photo acryl or photosensitive polyimide.

In addition, the multi-buffer layer 121a may be used by stacking inorganic insulating materials, such as silicon nitride (SiNx) or silicon oxide (SiO₂) in multiple layers, and may be used by stacking organic insulating materials and inorganic insulating materials in multiple layers.

The adhesive layer 121b may be disposed on the multi-buffer layer 121a. The adhesive layer 121b may be disposed on the multi-buffer layer 121a and on the substrate 110 exposed by the multi-buffer layer 121a in the bending region BA. The adhesive layer 121b may be formed of, but is not limited to, an acrylic resin, a silicone resin, and the like.

The planarization film 121c may be disposed on the adhesive layer 121b. The planarization film 121c may be disposed only in the active area AA, the bezel area BZ, and the pad area PAD, except for the bending region BA. The planarization film 121c may be formed of an organic insulating material, such as, but not limited to, a photosensitive photo acryl or photosensitive polyimide.

First wire patterns M0 may be disposed on the planarization film 121c, and the via contact layer 122a covering the first wire patterns M0 may be disposed. The first wire patterns M0 may be disposed on the planarization film 121c and on the adhesive layer 121b exposed by the planarization film 121c in the bending region.

Second wire patterns M1 may be disposed on the via contact layer 122a, and the first organic film 122b covering the second wire patterns M1 may be disposed. The second wire patterns M1 may be disposed in the active area AA, the bezel area BZ, and the pad area PAD, except for the bending region BA.

Third wire patterns M2 may be disposed on the first organic film 122b, and the second organic film 122c covering the third wire patterns M2 may be disposed. The third wire patterns M2 may be disposed in the active area AA, the bezel area BZ, and the pad area PAD, except for the bending region BA.

Fourth wire patterns M3 may be disposed on the second organic film 122c, and the third organic film 122d covering the fourth wire patterns M3 may be disposed. The fourth wire patterns M3 may be disposed in the active area AA, the bezel area BZ, and the pad portion PAD, except for the bending region BA.

Fifth wire patterns M4 may be disposed on the third organic film 122d. The fifth wire patterns M4 may be disposed in the active area AA, the bezel area BZ except for the bending region BA, and the pad portion PAD.

The bank patterns 130 may be disposed on the third organic film 122d, and the light-emitting element 10 may be disposed on the bank patterns 130. Each of the bank patterns 130 may be disposed under one light-emitting element or two light-emitting elements. The bank pattern 130 may be formed of an organic insulating material, such as, but not limited to, a photosensitive photo acryl or photosensitive polyimide. The bank pattern 130 may guide a position to which the light-emitting element will be attached during the transfer process for the light-emitting element. The bank pattern 130 may be omitted.

In the display apparatus according to an embodiment of the present disclosure, a groove is formed in the bending region BA, and the organic film in the active area AA must be formed such that the organic film is flattened taking into account the bending region where the groove is formed, so as to prevent the occurrence of a defect in which the light-emitting element is not properly transferred during the process of transferring the light-emitting element. In particular, an upper surface of the third organic film 122d affecting the transfer of the light-emitting element is to be flattened.

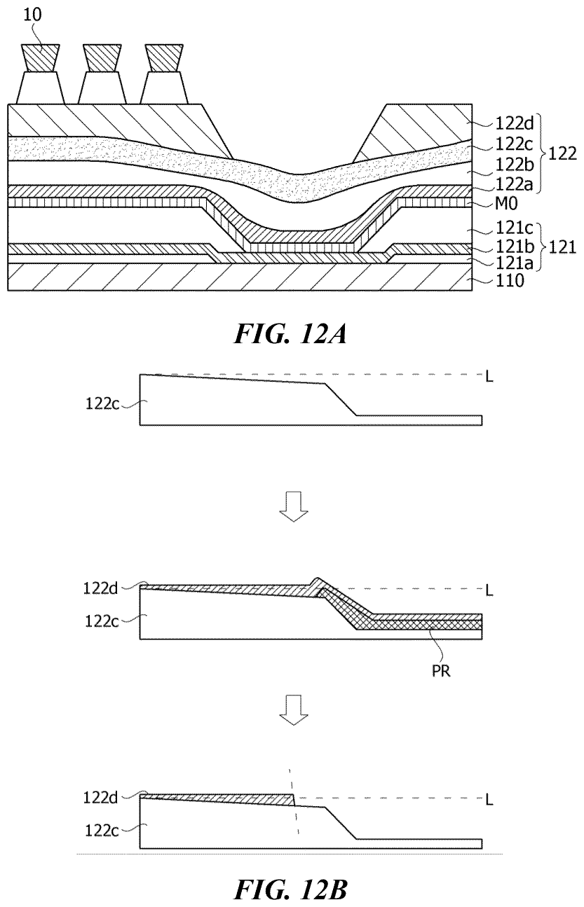

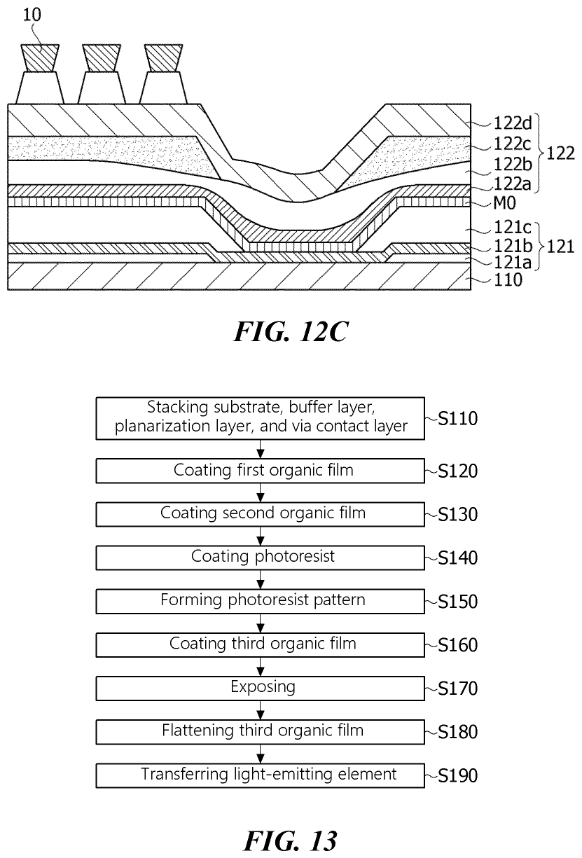

FIGS. 12A to 12C are drawings for illustrating a principle of coating an organic film in a bending region by comparison.

When the first organic film 122b, the second organic film 122c, and the third organic film 122d are sequentially deposited in the active area AA, the upper surface of the third organic film 122d is not flattened toward the groove region and is inclined from the bending region to the groove region, which causes defects in transferring the light-emitting element 10 to the third organic film 122d.

Accordingly, in an embodiment, an organic film is to be deposited using a photoresist pattern.

That is, referring to FIG. 12A, the first organic film 122b is deposited on the via contact layer 122a, the second organic film 122c is deposited on the first organic film 122b, and then the third organic film 122d is deposited using a photoresist pattern (PR).

When depositing and patterning the third organic film 122d with the photoresist pattern PR as shown in FIG. 12B, the upper surface of the third organic film 122d may not be inclined to the horizontal line L and remain flat.

Therefore, in this embodiment, the photoresist pattern is used to flatten the third organic film. When the upper surface of the third organic film is flattened, the transfer of light-emitting element to the third organic film will not cause defects.

Referring to FIG. 12C, an example is shown in which the first organic film 122b is deposited on the via contact layer 122a, the second organic film 122c is deposited using a photoresist pattern PR on the first organic film 122b, and the third organic film 122d is deposited.

Unlike FIG. 12A, when the photoresist pattern (PR) is used before the deposition of the second organic film 122c, the upper surface of the second organic film 122c is flattened as the second organic film 122c is removed from the bending region, so that the upper surface of the third organic film 122d, which is deposited on the upper surface of the second organic film 122c, is also flattened, and thus no defect occur in transferring the light-emitting element 10 to the upper surface of the third organic film 122d.

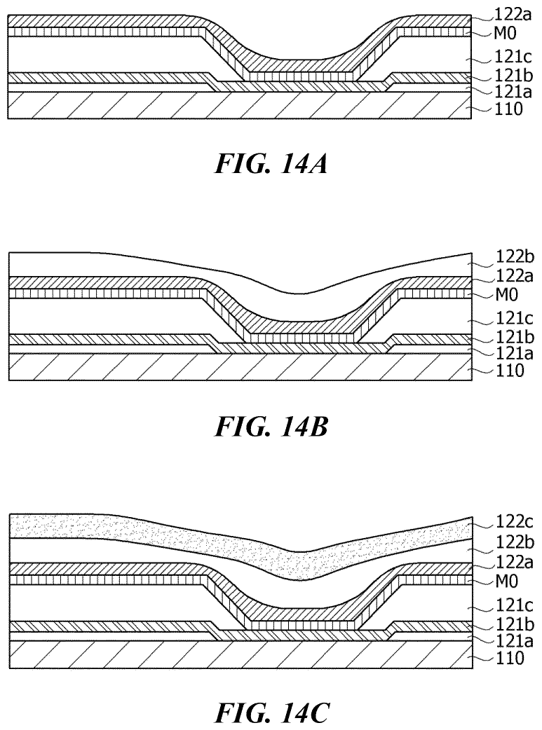

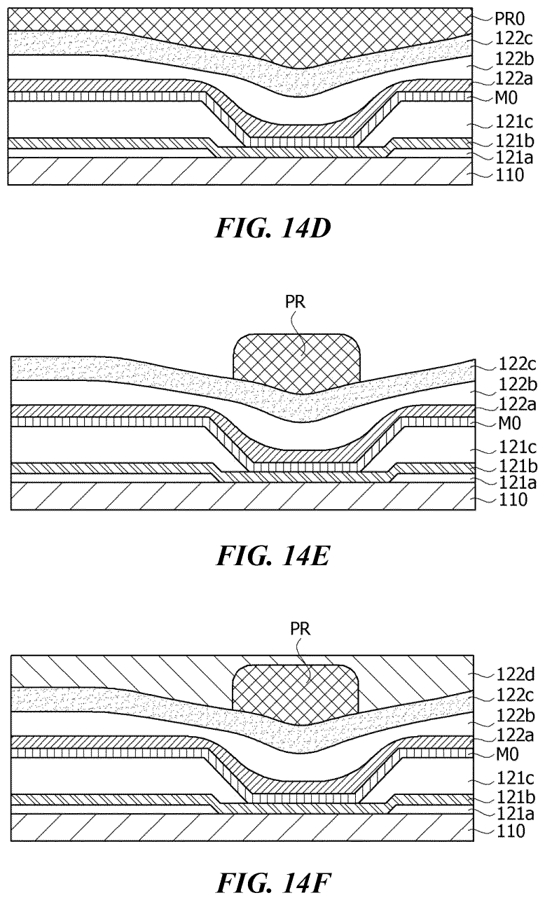

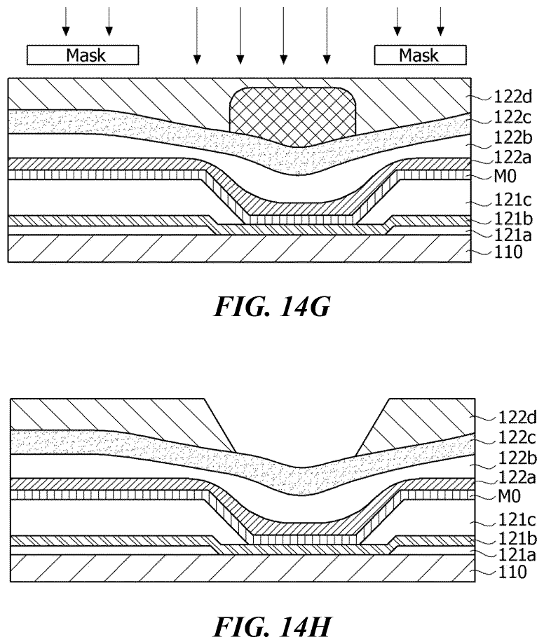

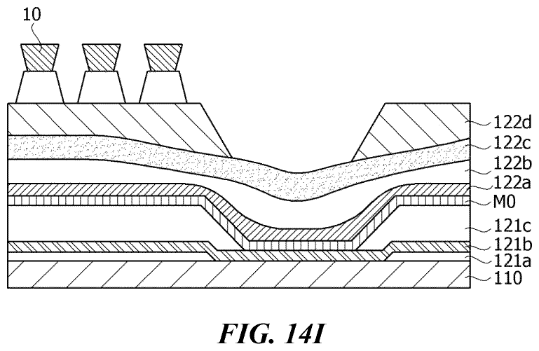

FIG. 13 is a diagram illustrating a method of manufacturing a display apparatus according to an embodiment of the present disclosure. FIGS. 14A to 14I are diagrams illustrating the respective processes of manufacturing method shown in FIG. 13. For convenience of drawing notation, the wire patterns M0 to M4 are not illustrated in FIGS. 14A to 14i.

Referring to FIGS. 13 and 14A, the substrate 110, the multi-buffer layer 121a, the adhesive layer 121b, the planarization film 121c, and the via contact layer 122a may be stacked sequentially (S110). In this process, the via contact layer 122a covering the first wire patterns M0 may be stacked after the first wire patterns M0 are formed on the planarization film 121c.

Referring to FIGS. 13 and 14B, the first organic film 122b may be formed on the via contact layer 122a (S120). In this process, after the second wire patterns M1 are formed on the via contact layer 122a, the first organic film 122b covering the second wire patterns M1 may be formed.

Referring to FIGS. 13 and 14C, the second organic film 122c may be formed on the first organic film 122b (S130). In this process, the third wire patterns M2 may be formed on the first organic film 122b, and then the second organic film 122c covering the third wire pattern M2 may be formed.

Referring to FIGS. 13 and 14D, a photoresist (PRO) may be coated on the second organic film 122c (S140). In this process, the fourth wire pattern M3 is formed on the second organic film 122c, and then the photoresist (PRO) covering the fourth wire pattern M3 may be coated.

Referring to FIGS. 13 and 14E, a photoresist pattern PR may be formed by performing an exposure process on the photoresist (PRO) formed on the second organic film 122c as a mask (S150).

Referring to FIGS. 13 and 14F, the third organic film 122d may be coated on the second organic film 122c on which the photoresist pattern PR is formed (S160).

Referring to FIGS. 13 and 14G, an upper portion of the third organic film 122d may be exposed using a mask (S170).

Referring to FIGS. 13 and 14H, the upper surface of the third organic film 122d may be flattened by performing an exposure process of the third organic film 122d and removing the third organic film 122d and the photoresist pattern PR corresponding to the bending region (S180). Thus, although the third organic film 122d may be formed in the active area, the bezel area, and the pad area, except for the bending region, the upper surface of the third organic film 122d may be flattened.

Referring to FIGS. 13 and 14I, the light-emitting element 10 may be transferred to the third organic film 122d corresponding to the active region (S190). Since the upper surface of the third organic film 122d may have been flattened, the light-emitting element is easily transferred to the upper surface of the third organic film 122d, thereby improving the transfer yield.

According to one or more embodiments of the present disclosure, a display apparatus may be described as follows.

According to one or more embodiments of the present disclosure, a display apparatus may include a substrate having a bending region between an active area and a pad area; a planarization film formed on the active area and the pad area in the substrate; a first organic film coated on the planarization film; a second organic film coated on the first organic film; a third organic film coated on the second organic film, wherein the third organic film is formed such that an upper surface thereof is flattened in the active region; and a plurality of light-emitting elements disposed on the third organic film.

The display apparatus may further include a multi-buffer layer formed on the active area and the pad area in the substrate; and an adhesive layer formed between the multi-buffer layer and the planarization film.

The display apparatus may further include a via contact layer formed on the planarization film and in the bending region of the substrate.

The third organic film may be flattened by a photoresist pattern disposed on the second organic film corresponding to the bending region.

The third organic film may be formed on the active area and the pad area.

The second organic film may have an upper surface flattened by a photoresist pattern disposed on the first organic film corresponding to the bending region.

The display apparatus may further include first wire patterns disposed on the planarization film, the via contact layer may be formed on the planarization film on which the first wire patterns are formed.

The first wire patterns may be formed on the planarization film and on an adhesive layer exposed in the bending region.

The display apparatus may further include second wire patterns disposed on the via contact layer, the first organic film is formed on the via contact layer on which the second wire patterns are disposed.

The display apparatus may further include third wire patterns disposed on the first organic film, the second organic film is formed on the first organic film on which the third wire patterns are disposed.

The display apparatus may further include fourth wire patterns disposed on the second organic film, the third organic film is formed on the second organic film on which the fourth wire patterns are disposed.

The display apparatus may further include fifth wire patterns disposed on the third organic film.

According to one or more embodiments of the present disclosure, a display apparatus may include a substrate having a bending region between an active area and a pad area; a planarization film formed on the active area and the pad area in the substrate; an organic film coated on the planarization film and on the substrate exposed in the bending region, wherein the organic film is formed so that an upper surface thereof is flattened in the active area; and a plurality of light-emitting elements transferred to the flattened organic film.

The display apparatus may further include a multi-buffer layer formed on the active area and the pad area in the substrate; and an adhesive layer formed between the multi-buffer layer and the planarization film.

The display apparatus may further include a via contact layer formed on the planarization film and in the bending region of the substrate.

The organic film may be flattened by a photoresist pattern disposed in the bending region.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate having a bending region between an active area and a pad area;
a planarization film on the active area and the pad area in the substrate;
a first organic film on the planarization film;
a second organic film on the first organic film;
a third organic film on the second organic film, the third organic film having an upper surface, the upper surface of the third organic film being flat in the active region; and
a plurality of light-emitting elements disposed on the third organic film.

2. The display apparatus of claim 1, further comprising:
a multi-buffer layer on the active area and the pad area in the substrate; and
an adhesive layer between the multi-buffer layer and the planarization film.

3. The display apparatus of claim 2, further comprising:
a via contact layer on the planarization film and in the bending region of the substrate.

4. The display apparatus of claim 1, wherein the third organic film is flattened by a photoresist pattern disposed on the second organic film corresponding to the bending region.

5. The display apparatus of claim 1, wherein the third organic film is on the active area and the pad area.

6. The display apparatus of claim 1, wherein the second organic film has an upper surface flattened by a photoresist pattern disposed on the first organic film corresponding to the bending region.

7. The display apparatus of claim 3, further comprising:
first wire patterns disposed on the planarization film,
wherein the via contact layer is on the planarization film on which the first wire patterns are formed.

8. The display apparatus of claim 7, wherein the first wire patterns are on the planarization film and on an adhesive layer exposed in the bending region.

9. The display apparatus of claim 7, further comprising:
second wire patterns disposed on the via contact layer,
wherein the first organic film is on the via contact layer on which the second wire patterns are disposed.

10. The display apparatus of claim 9, further comprising:
third wire patterns disposed on the first organic film,
wherein the second organic film is on the first organic film on which the third wire patterns are disposed.

11. The display apparatus of claim 10, further comprising:
fourth wire patterns disposed on the second organic film,
wherein the third organic film is on the second organic film on which the fourth wire patterns are disposed.

12. The display apparatus of claim 11, further comprising:
fifth wire patterns disposed on the third organic film.

13. A display apparatus comprising:
a substrate having a bending region between an active area and a pad area;
a planarization film on the active area and the pad area in the substrate;
an organic film on the planarization film and on the substrate exposed in the bending region, wherein the organic film includes an upper surface that is planar in the active area; and
a plurality of light-emitting elements transferred to the planar upper surface of the organic film.

14. The display apparatus of claim 13, further comprising:
a multi-buffer layer on the active area and the pad area in the substrate; and
an adhesive layer between the multi-buffer layer and the planarization film.

15. The display apparatus of claim 14, further comprising:
a via contact layer on the planarization film and in the bending region of the substrate.

16. The display apparatus of claim 13, wherein the organic film is flattened by a photoresist pattern disposed in the bending region.
